(19) United States
(12) Patent Application Publication
(10) Pub. No.: US 2025/0031440 A1
(43) Pub. Date: Jan. 23, 2025

(54) MULTI-SILICIDE STACKED FIELD-EFFECT TRANSISTORS

(71) Applicant: INTERNATIONAL BUSINESS MACHINES CORPORATION, Armonk, NY (US)

(72) Inventors: Domingo Ferrer, Clifton Park, NY (US); Jingyun Zhang, Albany, NY (US); Teresa J. Wu, Rexford, NY (US); Utkarsh Bajpai, Delmar, NY (US)

(21) Appl. No.: 18/224,653

(22) Filed: Jul. 21, 2023

(51) Int. Cl. H01L 27/092; H01L 29/06; H01L 29/423; H01L 29/49; H01L 29/66; H01L 29/775

(52) U.S. Cl. CPC H01L 27/092; H01L 29/0673; H01L 29/42392; H01L 29/4975; H01L 29/66439; H01L 29/775

(57) ABSTRACT

A semiconductor structure, a system, and a method of forming a multi-silicide structure for stacked FETs within the semiconductor. The semiconductor structure may include an NFET. The semiconductor structure may also include a PFET. The semiconductor structure may also include an NFET silicide proximately connected to the NFET, where the NFET silicide is a first material. The semiconductor structure may also include a PFET silicide proximately connected to the PFET, where the PFET silicide is a second material different than the first material. The system may include the semiconductor structure. The method may include forming an NFET silicide proximately connected to an NFET, where the NFET silicide is a first material. The method may also include forming a PFET silicide proximately connected to a PFET, where the PFET silicide is a second material different than the first material.

### BACKGROUND

The present disclosure relates to semiconductors and stacked transistors and, more specifically, to a multi-silicide structure for stacked field-effect transistors (FETs). Semiconductors, such as complementary metal-oxide-semiconductors (CMOS), are commonly used in computer chips and computer technology. These semiconductor chips/devices typically include transistor(s). Transistors are devices which may be used to switch or amplify electric current or voltage.

FETs use an electric field effect to control current flow within a semiconductor. FETs have three terminals—a source, a drain, and a gate. The source may introduce/provide current to the transistor, the drain may be the terminal that provides the output current, and the gate may be used to control the current flow from the source to the drain. Specifically, FETs may use the electric charge of their gates to affect and control the current flow through the channel.

Current may flow using charge carriers that may be either electrons or holes. Electron charge carriers may be negatively charged particles (i.e., electrons) that carry charge and create an electric current. Hole charge carriers (referred to herein as holes) are positions on the FET channel that lack an electron (for instance, at positions of positive charge that is equal to the negative charge of an electron and/or positions where an electron could or should be). These holes may be positive charges, and they may move in an opposite direction of electrons, in some instances. The electric charge and/or voltage of the FET gates may be used to control the movements of the electrons and/or holes, which may then affect the current and charge being transmitted through the channel from the source to the drain.

One common type of FET is a finFET. FinFETs, as referred to herein, may be FETs in a vertical fin shape. FinFETs may have vertically stacked channels, and vertically stacked components in general, in order to form the tall, narrow fin shape of a finFET. Another common type of FET is a nanosheet FET. Nanosheet FETs may have multiple nanosheets stacked (for example, horizontally) on top of each other.

### SUMMARY

The present disclosure provides a semiconductor, a system, and a method of forming a multi-silicide structure for stacked FETs within the semiconductor. The semiconductor structure may include an N-channel field-effect transistor (NFET). The semiconductor structure may also include a P-channel field-effect transistor (PFET). The semiconductor structure may also include an NFET silicide proximately connected to the NFET, where the NFET silicide is a first material. The semiconductor structure may also include a PFET silicide proximately connected to the PFET, where the PFET silicide is a second material different than the first material.

The system may include a semiconductor structure. The semiconductor structure may include an NFET. The semiconductor structure may also include a PFET. The semiconductor structure may also include an NFET silicide proximately connected to the NFET, where the NFET silicide is a first material. The semiconductor structure may also include a PFET silicide proximately connected to the PFET, where the PFET silicide is a second material different than the first material. The semiconductor structure may also include a silicide contact for the PFET.

The method may include forming an NFET silicide proximately connected to an NFET, where the NFET silicide is a first material. The method may also include forming a PFET silicide proximately connected to a PFET, where the PFET silicide is a second material different than the first material.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 depicts a cross-sectional view of an Ru-silicide stacked FET structure, according to some embodiments.

FIG. 2 depicts a top down view of a multi-silicide structure with various cross-sections, according to some embodiments.

FIGS. 3A-3D depict various cross-sectional views of a first intermediate step of forming a multi-silicide stacked FET structure, according to some embodiments.

FIGS. 4A-4D depict various cross-sectional views of a second intermediate step of forming a multi-silicide stacked FET structure, according to some embodiments.

FIGS. 5A-5D depict various cross-sectional views of a third intermediate step of forming a multi-silicide stacked FET structure, according to some embodiments.

FIGS. 6A-6D depict various cross-sectional views of a fourth intermediate step of forming a multi-silicide stacked FET structure, according to some embodiments.

FIGS. 7A-7D depict various cross-sectional views of a fifth intermediate step of forming a multi-silicide stacked FET structure, according to some embodiments.

FIGS. 8A-8D depict various cross-sectional views of a sixth intermediate step of forming a multi-silicide stacked FET structure, according to some embodiments.

FIGS. 9A-9D depict various cross-sectional views of a seventh intermediate step of forming a multi-silicide stacked FET structure, according to some embodiments.

FIGS. 10A-10D depict various cross-sectional views of an eighth intermediate step of forming a multi-silicide stacked FET structure, according to some embodiments.

FIGS. 11A-11D depict various cross-sectional views of a ninth intermediate step of forming a multi-silicide stacked FET structure, according to some embodiments.

FIGS. 12A-12D depict various cross-sectional views of a tenth intermediate step of forming a multi-silicide stacked FET structure, according to some embodiments.

FIGS. 13A-13D depict various cross-sectional views of an eleventh intermediate step of forming a multi-silicide stacked FET structure, according to some embodiments.

FIGS. 14A-14D depict various cross-sectional views of a twelfth intermediate step of forming a multi-silicide stacked FET structure, according to some embodiments.

FIGS. 15A-15D depict various cross-sectional views of a thirteenth intermediate step of forming a multi-silicide stacked FET structure, according to some embodiments.

FIGS. 16A-16D depict various cross-sectional views of a fourteenth intermediate step of forming a multi-silicide stacked FET structure, according to some embodiments.

FIGS. 17A-17D depict various cross-sectional views of a fifteenth intermediate step of forming a multi-silicide stacked FET structure, according to some embodiments.

FIGS. 18A-18D depict various cross-sectional views of a fully-formed multi-silicide stacked FET structure, according to some embodiments.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

Aspects of the present disclosure relate to semiconductors and stacked transistors and, more specifically, to a multi-silicide structure for stacked field-effect transistors (FETs). While the present disclosure is not necessarily limited to such applications, various aspects of the disclosure may be appreciated through a discussion of various examples using this context.

Transistors, such as field-effect transistors (FETs), may be used within a system (for example, within a semiconductor) to switch or amplify electric current or voltage. FETs may have two typical configurations, N-channel FETs and P-channel FETs. N-channel FETs introduce (for example, through doping) an n-type impurity to the semiconductor material of the channel between the source and the drain, and P-channel FETs introduce a p-type impurity to the semiconductor material of the channel.

For n-type impurities, arsenic, phosphorous, or any other n-type material may be added to the silicon. N-type materials may have five electrons in their outer orbitals. When the n-type materials are combined with the silicon of the semiconductor, the fifth electron may not have anything to bond to and may freely move around, which may allow an electric current to flow through the silicon semiconductor channel and the extra electrons (i.e., the electron charge carriers). Because there are extra electrons from the n-type materials, the majority carrier/charge carrier for N-channel FETs are electrons.

In P-channel FETs, p-type impurities such as boron, gallium, etc., may be added to the silicon semiconductor(s) for the silicon doping. The p-type materials may have three electrons in their outer orbitals which, when added to silicon, may form holes (i.e., may lack electrons) in the valence bonds of the silicon atoms. Because there are holes in the valence bonds due to the p-type materials, the majority carrier/charge carrier for P-channel FETs are holes. An N-channel FET may be referred to herein as an NFET and a P-channel FET may be referred to herein as a PFET.

In some instances, it may be beneficial to have multiple FETs connected to each other. For example, in logic gate designs, an N-gate from an NFET may be electrically connected to a P-gate from a PFET in order to form an input for the logic gate. A logic gate may be a circuit with one or more inputs (for example, any number of inputs), but only one output. In some instances, for example, combining NFET and PFET in a logic gate design can eliminate large current leakage from VDD (a positive supply voltage) to ground in a static/non-switching period, as one of the transistors will be off which may prevent different shorts between VDD and ground. This design is conventionally referred to as a complementary metal-oxide-semiconductor (CMOS) logic design. Because of the benefits of combining NFET and PFET in a logic gate design, various logic designs may include NFET and PFET pairs.

As technology has advanced, it has become increasingly beneficial to have large amounts of technology and components in very small spaces. One method of fitting components in a small area, without reducing the capabilities of the components, is to stack transistors. Stacking transistors may increase the height of the semiconductor chip, but may reduce the area on the chip taken up by transistors. This may help allow for more components on the surface of a chip or may allow for a smaller chip, in some instances. For example, for logic gate designs, the connected NFET and PFET may be stacked on top of each other in order to have the benefit of the NFET-PFET pair (discussed above) while also saving space and reducing the area on the chip taken up by the NFET and PFET.

However, due to the stacked and compact architecture of stated transistors, there may be a limited amount of space for silicide formation (for example, as junctions and/or contacts between front-end-of-line (FEOL) portions (such as source, drain, gate, etc. portions of the transistors) and back-end-of-line (BEOL) portions (such as interconnects or other components) of a semiconductor). Further, due to the limited space for silicide(s), a very thin metal may be necessary for silicide formation, therefore the metal material(s) that can be used as part of the silicide may be limited. Because of the size/space limitations for the silicide and the limited materials that can be used for the silicide, the silicide material(s) in conventional stacked transistors may have a higher resistance and a higher capacitance than desired. A decreased resistance and decreased capacitance may allow for improved and/or increased current flow between the silicide(s) and the various components of the stacked transistors.

The present disclosure provides a semiconductor, a system, and a method of forming a multi-silicide structure for stacked FETs within the semiconductor. A multi-silicide structure may allow for different silicides to be used for the different transistors (NFETs and PFETs) in order to better customize the silicides to the specific transistor. Further, the materials used as silicides may have improved resistance (e.g., a lower/decreased resistance) and have/be associated with improved capacitance (e.g., a lower/decreased capacitance) compared to conventional silicide materials (for example, nickel, cobalt, nickel-platinum, etc.).

For instance, a multi-silicide structure may use a first material (such as titanium (Ti), for example) for the silicide in an NFET structure, and a second material (such as ruthenium (Ru), for example) for the silicide in a PFET structure. Both Ti and Ru may have low resistance and capacitance, and may be able to be in very thin forms, which may help improve/increase current flow between the silicide(s) and the various components of the stacked transistors (compared to conventional stacked transistors).

In addition, Ru may have a reduced Schottky barrier height, compared to Ti, which may be an advantage for PFET structures. A Schottky barrier, as referred to herein, refers to a potential energy barrier between a metal and a semiconductor, and a Schottky barrier height refers to a difference between a work function of the metal and an electron affinity of the semiconductor. In some instances, it may be advantageous, particularly for PFET structures (as they have hole charge carriers), to have a low Schottky barrier height. For instance, device performance may be dependent on contact resistance(s), which is a function of Schottky barrier height (for example, the Schottky barrier height may have a large effect on contact resistance and contact resistivity). Therefore, it may improve the functionality of stacked transistors to have a PFET silicide material (i.e., a silicide material within a PFET structure) with a lower/reduced Schottky barrier height than an NFET silicide material (i.e., a silicide material within an NFET structure).

In some instances, because of the patterning method used for a silicide material such as Ru (for example, compared to Ti-silicide), sidewalls may be patterned/formed between the PFET silicide and other components of the stacked transistor structure. This may allow for a low-k dielectric to be added as a sidewall around the PFET silicide material. A low-k dielectric (for example, such as SiCOH, parylene, silicon nitride (SiN), or any other low-k dielectric material) may have numerous advantages, including decreasing/reducing capacitance and avoiding electrical shorts (such as top-epi shorts). A low-k dielectric, as referred to herein, may be a dielectric material with a lower dielectric constant relative to silicon dioxide (SiO₂). In some instances, as discussed further herein, the low-k dielectric sidewalls may surround a PFET contact (made of the PFET silicide material) but not a PFET silicide junction (for example, between the contact and stacked nanosheets).

However, other silicide materials, such as Ti, may have various benefits within a transistor structure. For example, a Ti-silicide may act as a scavenger for native oxide on a junction (for example, between FEOL and BEOL components) and may consume, for example, 2 nanometers of epi per nanometer of metal. In addition, Ti-silicide may have thermodynamic stability which may help prevent electrical shorts (for example, that have been observed in other silicides such as nickel-silicide, for instance). Therefore, various silicide materials (such as Ti-silicide and Ru-silicide) may each have different benefits within a transistor structure.

Although silicides are discussed herein, other compounds (for example, germanides) may also be used. For example, an NFET may include a Ti-germanide and a PFET may include a Ru-germanide.

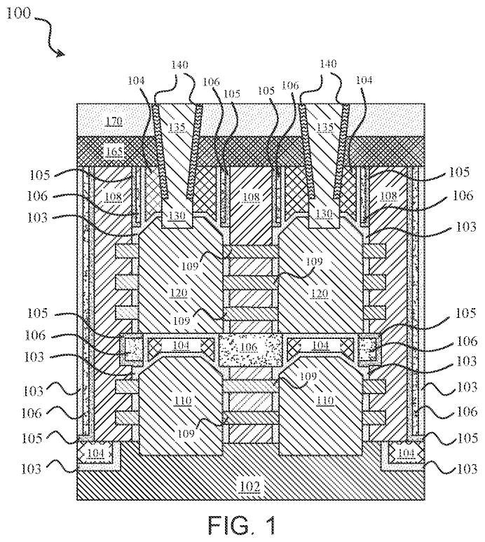

Referring now to FIG. 1, a cross-sectional view of an Ru-silicide stacked FET structure 100 is depicted, according to some embodiments. Stacked FET structure 100 includes a substrate 102 with NFETs 110 and PFETs 120 stacked on top of the substrate 102. The PFETs 120 may include silicides 130 and contacts 135. In some instances, the silicides 130 and the contacts 135 may be made of a same PFET silicide material (for example, Ru-silicide), however the contacts 135 (made of the PFET silicide material) may act as contacts between the PFET and other components of a semiconductor, and the silicides 130 may act as a junction between the PFETs 120 and the contacts 135. Therefore, the junction portions may be referred to herein as silicides 130 and the contact portions may be referred to herein as the contacts 135. Having the PFET silicides 130 as a material such as Ru-silicide may allow for silicide materials that can be thin (for example, as necessitated by the spatial constraints of semiconductors and stacked FETs) while also having low resistance and having/being associated with a low capacitance (for example, when compared to conventional materials). Further, a PFET silicide 130 material such as Ru-silicide may improve the functionality of the PFETs 120 due to the low Schottky barrier height (discussed further herein).

In some instances, as depicted in stacked FET structure 100, there may be low-k dielectric 140 (also referred to herein as low-k dielectric sidewalls 140) surrounding contacts 135. Although low-k dielectric 140 is depicted as only surrounding the sidewalls of contacts 135, there may be instances where low-k dielectric 140 surrounds sidewalls of the silicides 130 and/or where low-k dielectric 140 further includes a low-k dielectric barrier between the silicides 130 and the contacts 135. In some instances, the low-k dielectric may be made of materials such as such as SiCOH, parylene, SiN, SiO₂, or any other low-k dielectric material. As discussed herein, low-k dielectric sidewalls 140 may have numerous advantages for an FET, such as reducing capacitance, avoiding electrical shorts, etc.

Although stacked FET structure 100 does not depict NFET silicides (i.e., silicides within the NFET 110 regions of the stacked FET structure 100), stacked FET structure 100 may still include NFET silicides. In some instances, these silicides may simply be viewable in a different cross-section than depicted in FIG. 1 (for example, in cross-section B, as discussed and depicted further herein).

In some instances, as depicted herein, NFETs 110 and PFETs 120 may include nanosheets 109. In some instances, the nanosheets 109 may include silicon (Si) (or silicon compound) materials. In some instances (not depicted), NFETs 110 and PFETs 120 may be other forms of transistors (such as finFET transistors) and, in some instances, may not include nanosheets 109.

Stacked FET structure 100 may include metals 108 (for example, tungsten (W), cobalt (Co), etc.). These metals 108 may be used as contacts in source/drain or gate regions of the NFETs 110 and PFETs 120, in some instances. Stacked FET structure 100 may also include various dielectric/dielectric insulator materials (such as dielectric 103, 104, 105, and 106). In some instances, as depicted in FIG. 1, the various dielectrics (103, 104, 105, and 106) may be different dielectric materials. For instance, different dielectric materials may have different benefits/advantages—therefore it may be beneficial to utilize different dielectric materials depending on their purpose and/or the materials they are surrounding and/or near. For example, dielectric 103 may be a material such as SiN, dielectric 104 may be a material such as an oxide, dielectric 105 may be a material such as silicon oxide (SiO₂), silicon nitride (SiN), etc. and dielectric 106 may be a material such as silicoboron carbonitride (SiBCN). In some instances, dielectrics 103, 104, 105, and/or 106 may be the same/similar materials. In some instances, the various dielectrics 103, 104, 105, and 106 may help protect the various components of the stacked FET structure 100 and may help insulate/prevent unwanted heat and/or current transfer between components.

In some instances, as depicted in FIG. 1, stacked FET structure 100 may include dielectric layers 165 and 170 above (for example, when viewing stacked FET structure 100 from the cross-section depicted in FIG. 1) metal 108 and surrounding portions of low-k dielectric 140. In some instances, dielectric layers 165 and 170 may be different materials. For example, dielectric 165 may be a material such as SiN, SiO₂, etc. and dielectric 170 may be a material such as SiN. In other instances, dielectric layers 165 and 170 may be the same/similar materials.

Stacked FET structure 100 may be an example structure for multi-silicide stacked FETs. For example, although stacked FET structure 100 depicts NFET 110 as a bottom FET structure (when viewing from the cross-section depicted in FIG. 1) and PFET 120 as a top FET structure, in some instances PFET 120 may be a bottom FET and NFET 110 may be a top FET. In these instances, silicides 130 may be Ti-silicides and the bottom PFET silicides (not depicted in FIG. 1) may be Ru-silicides. Further, although stacked FET structure 100 depicts two NFETs 110 and two PFETs 120, any number of NFETs and PFETs (and their corresponding components, such as silicides 130, contacts 135, etc.) may be used.

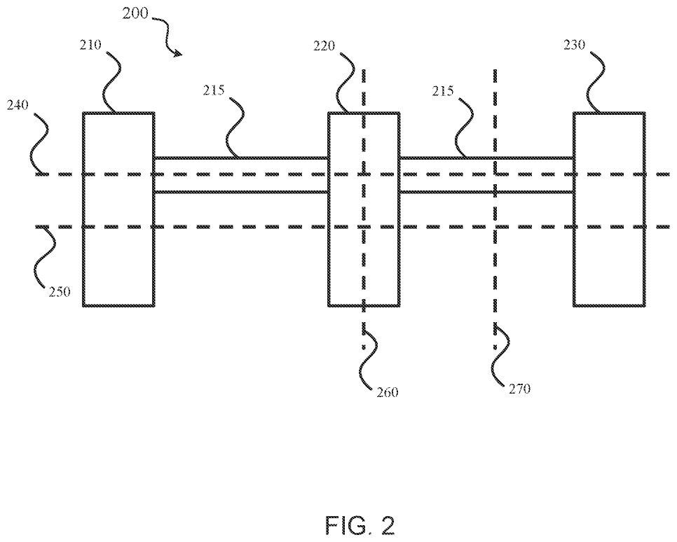

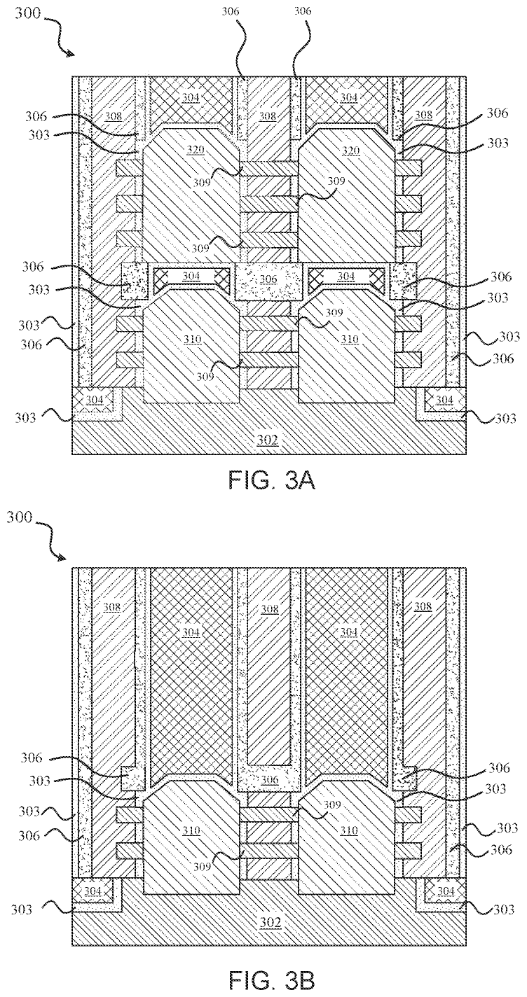

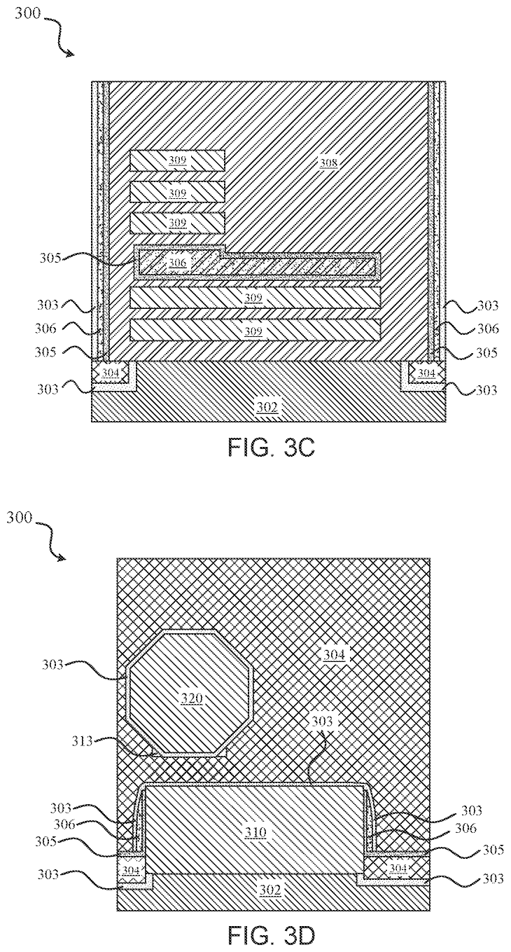

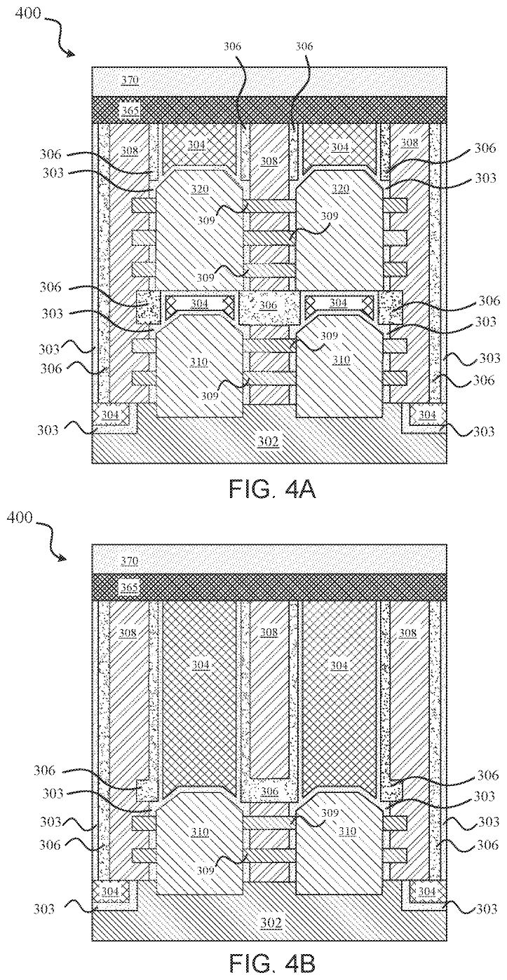

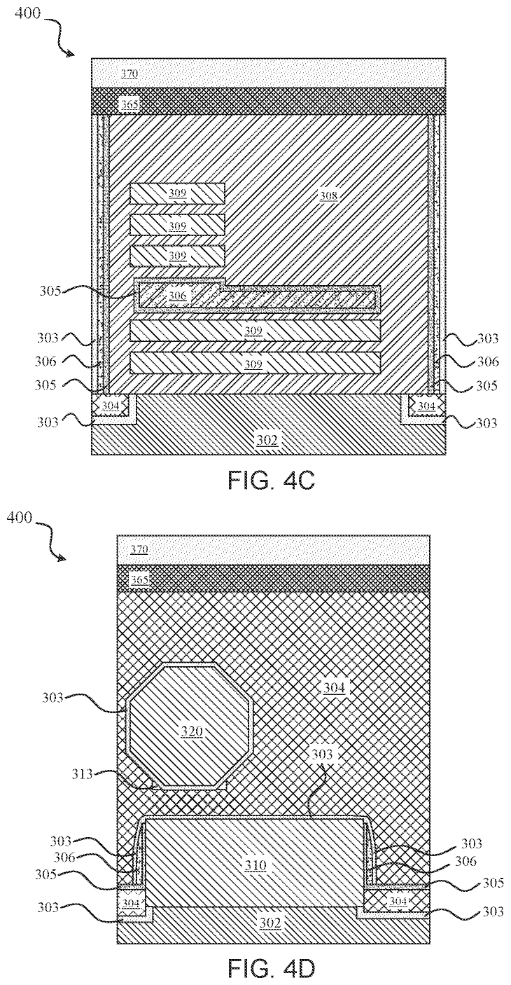

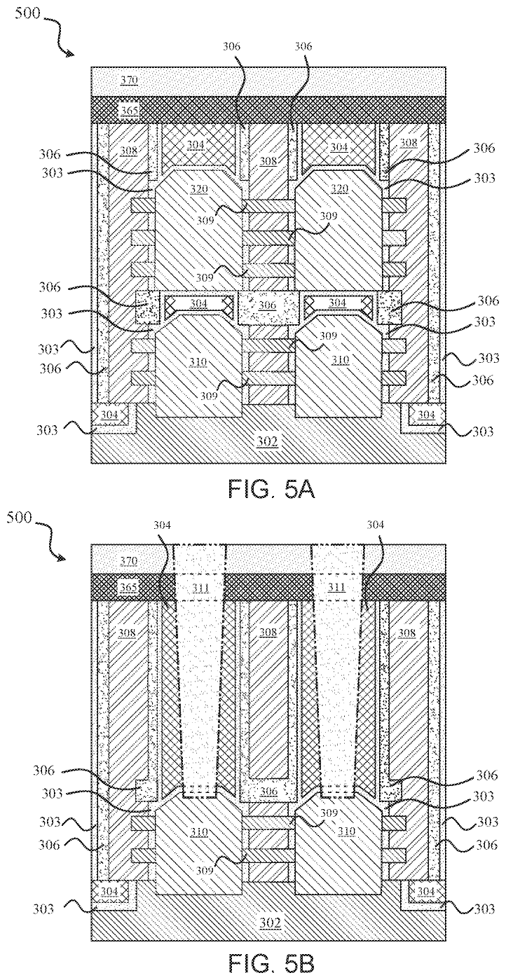

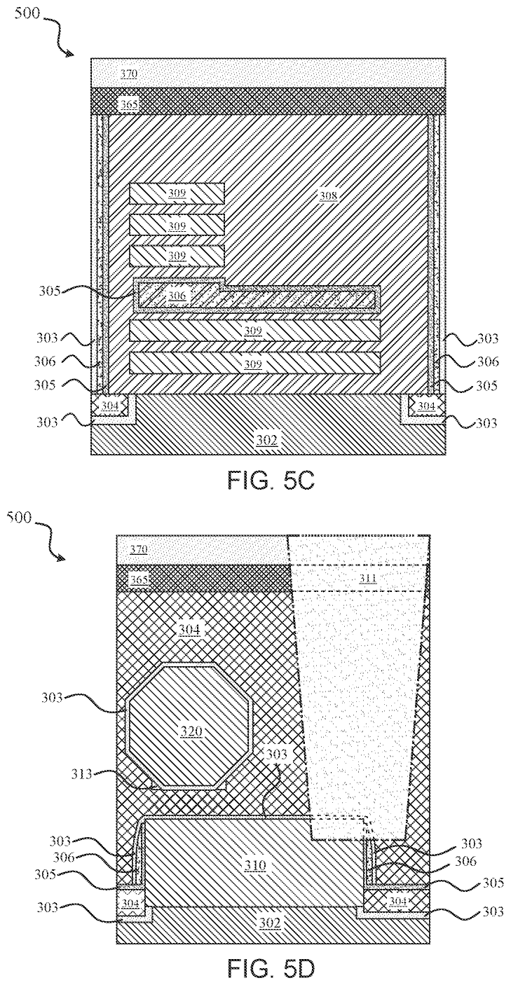

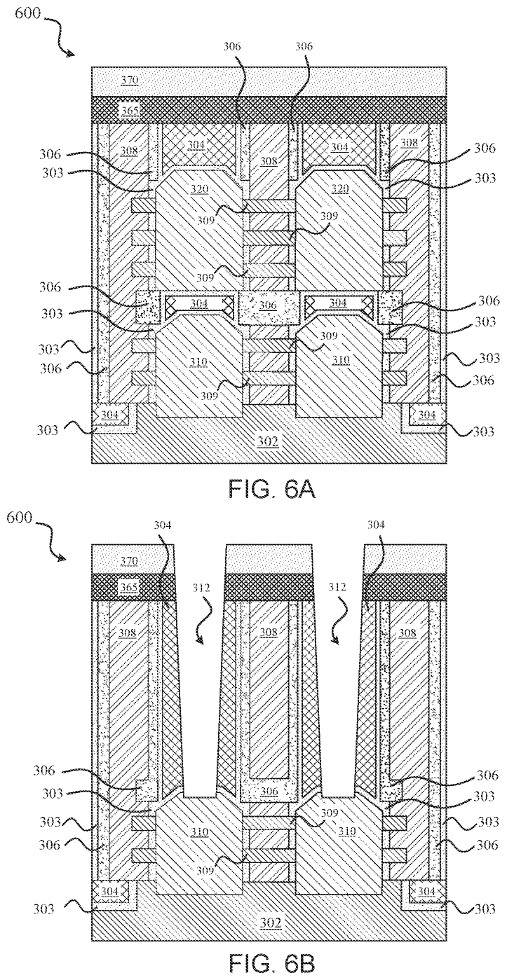

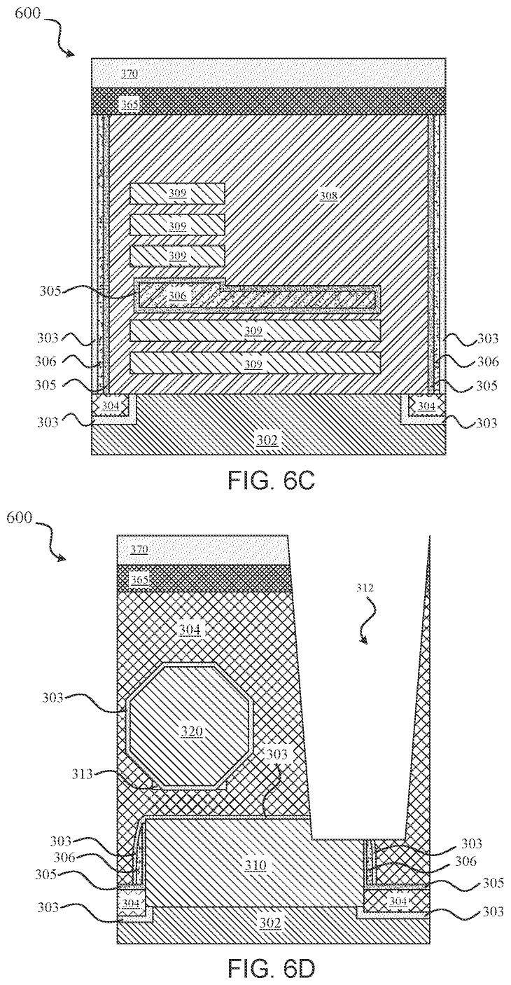

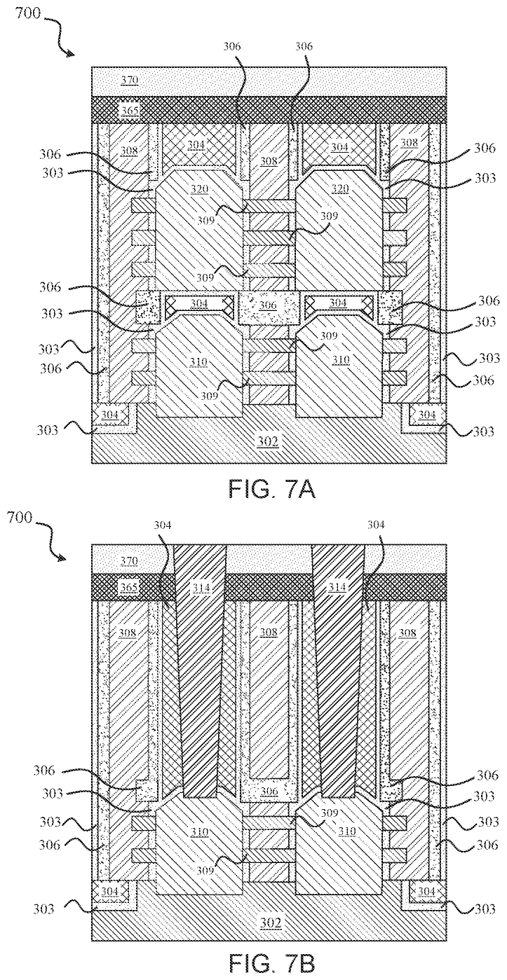

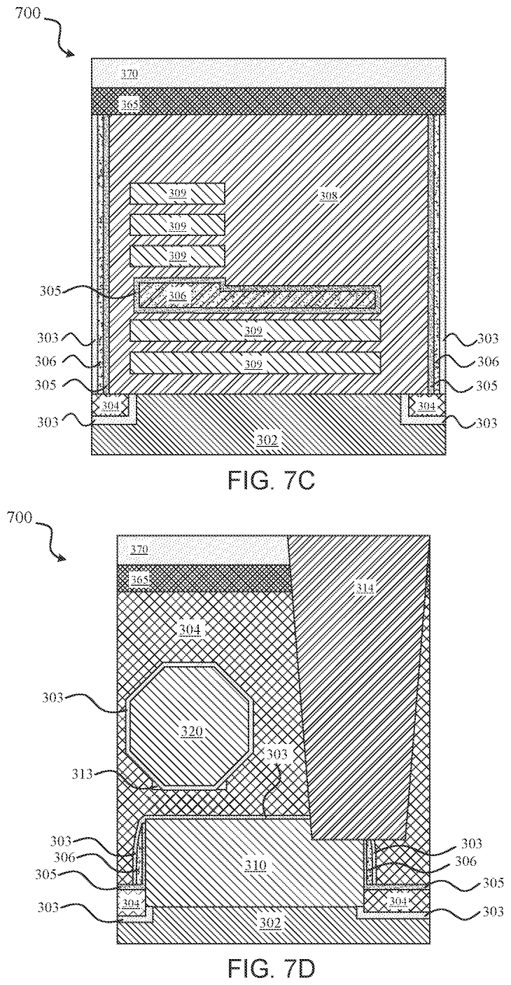

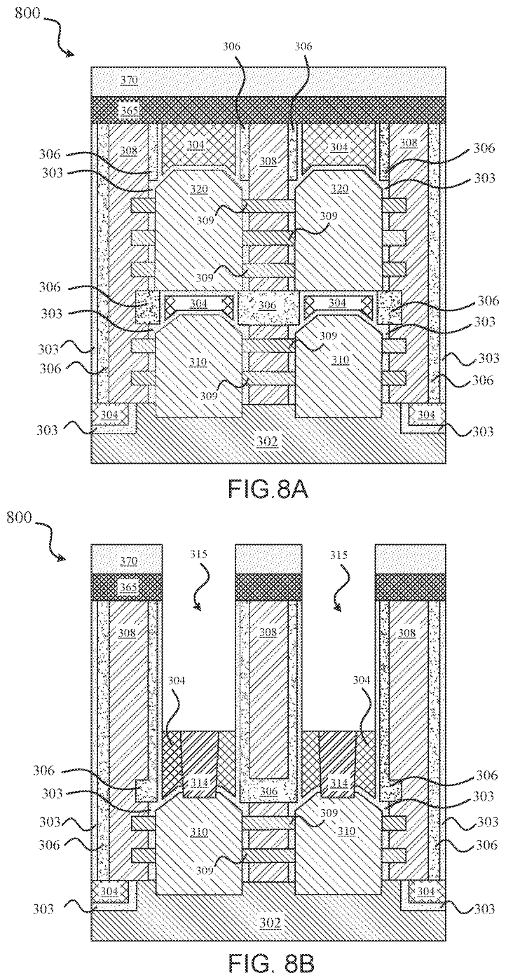

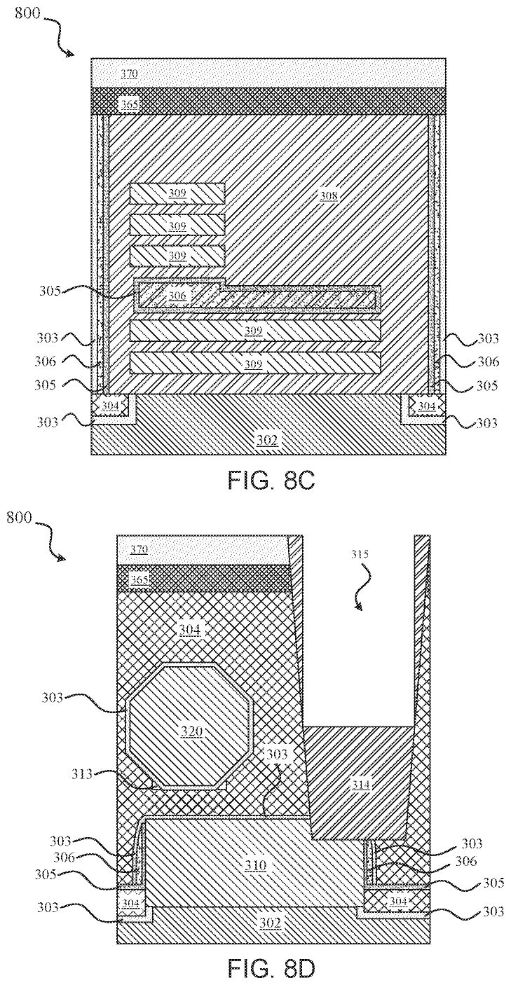

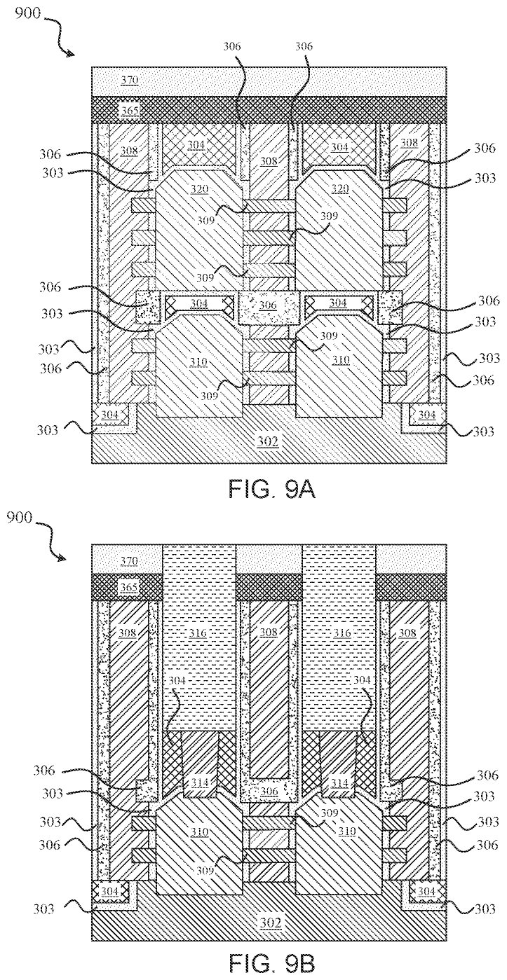

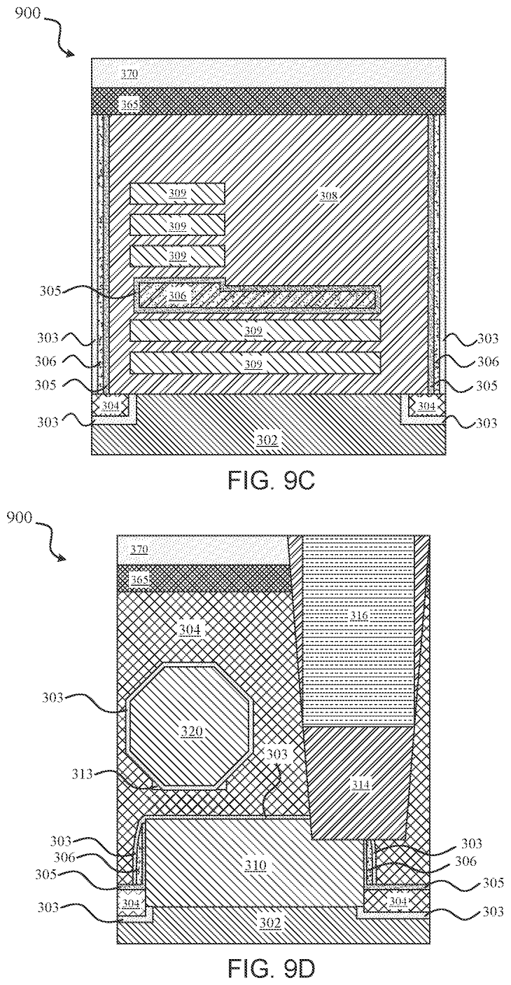

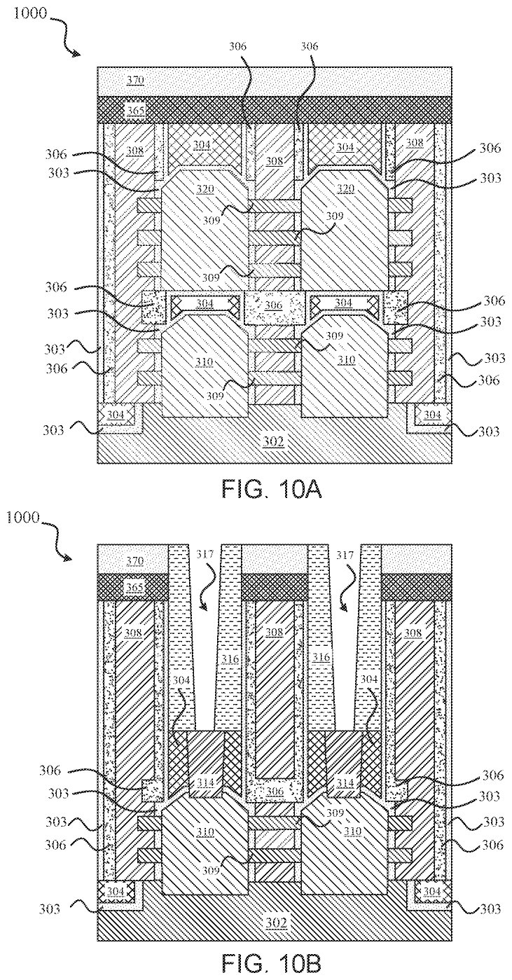

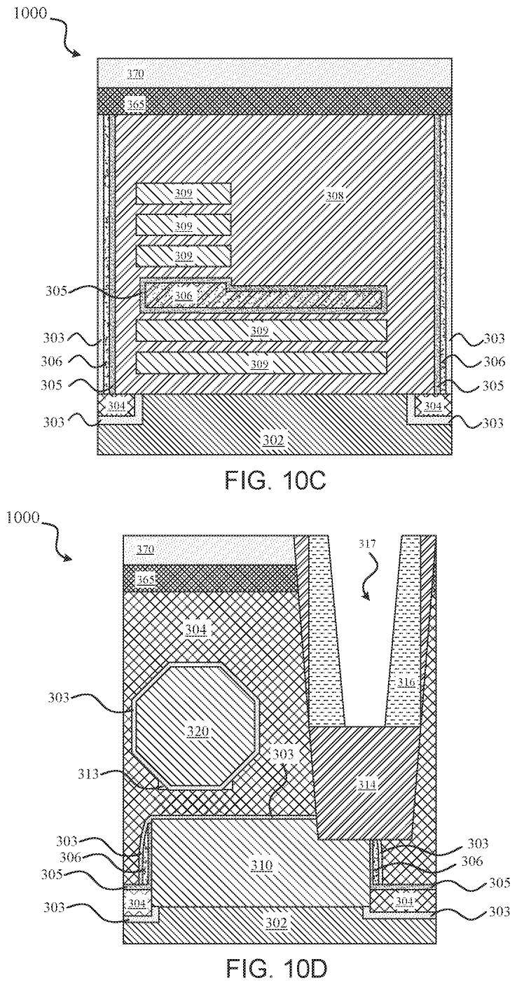

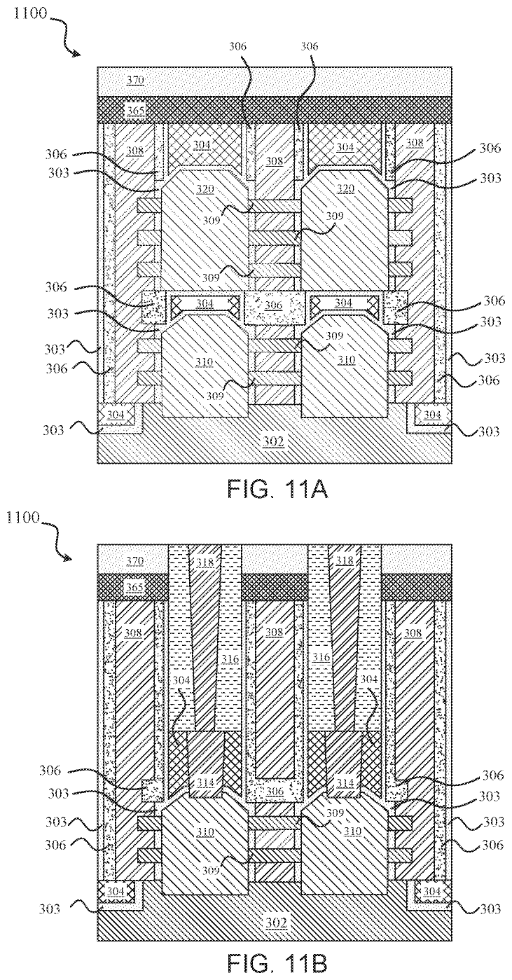

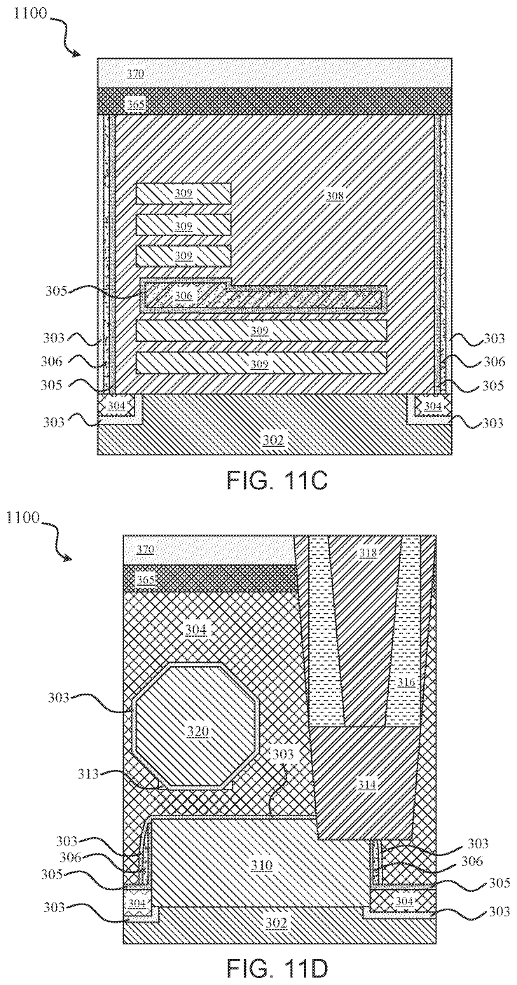

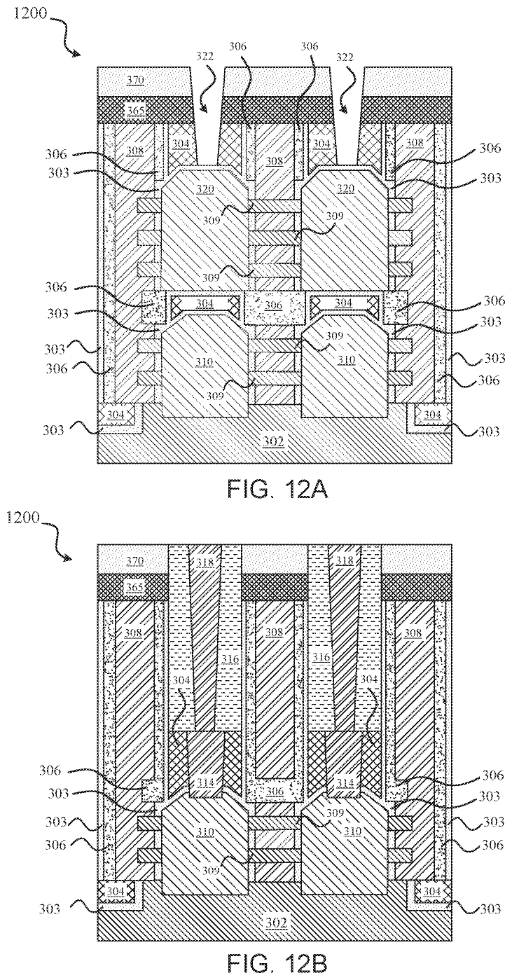

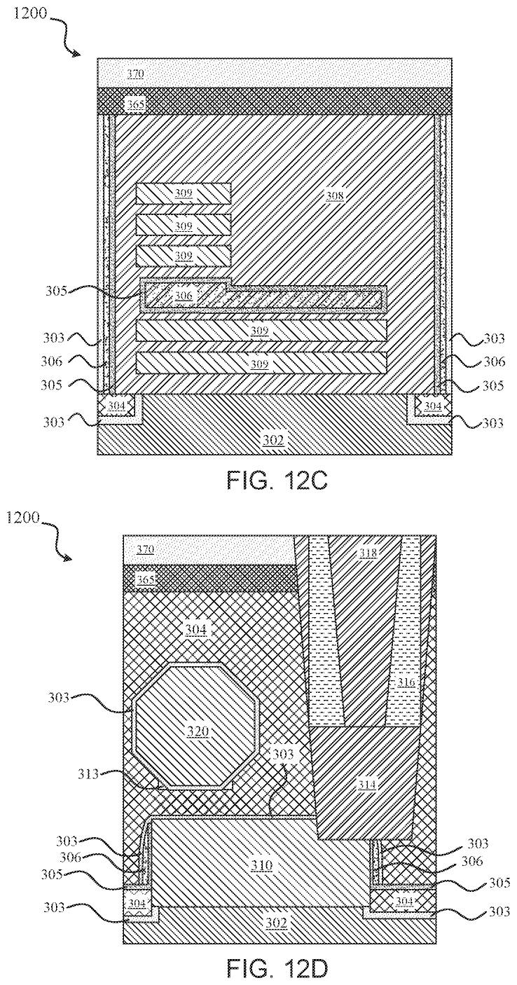

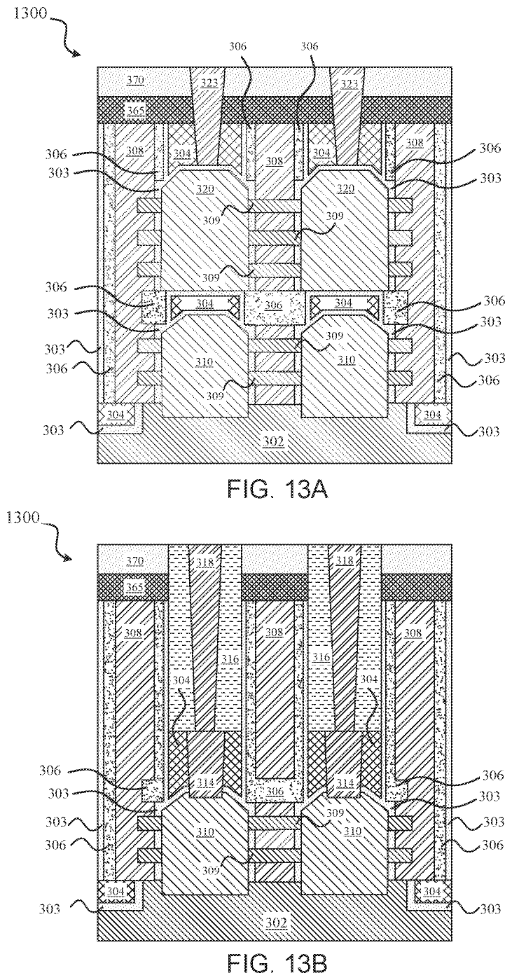

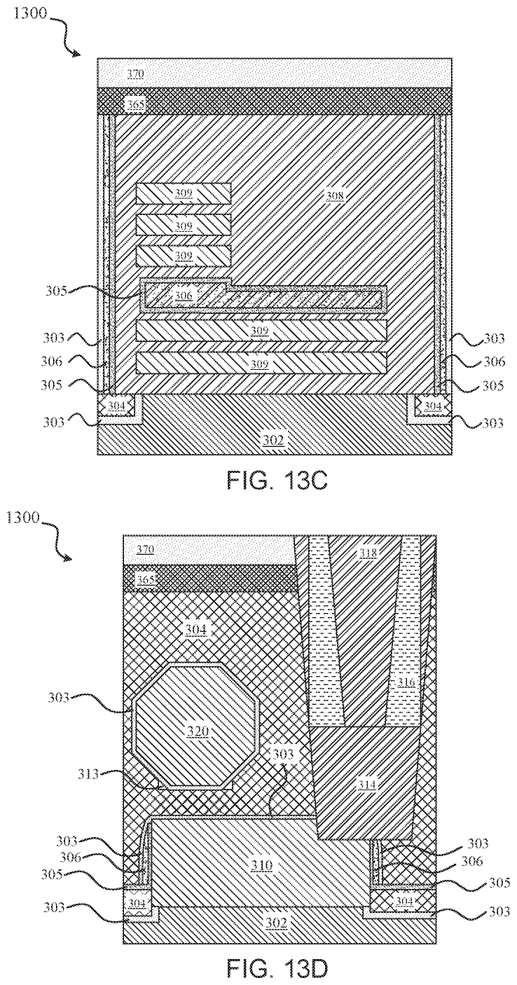

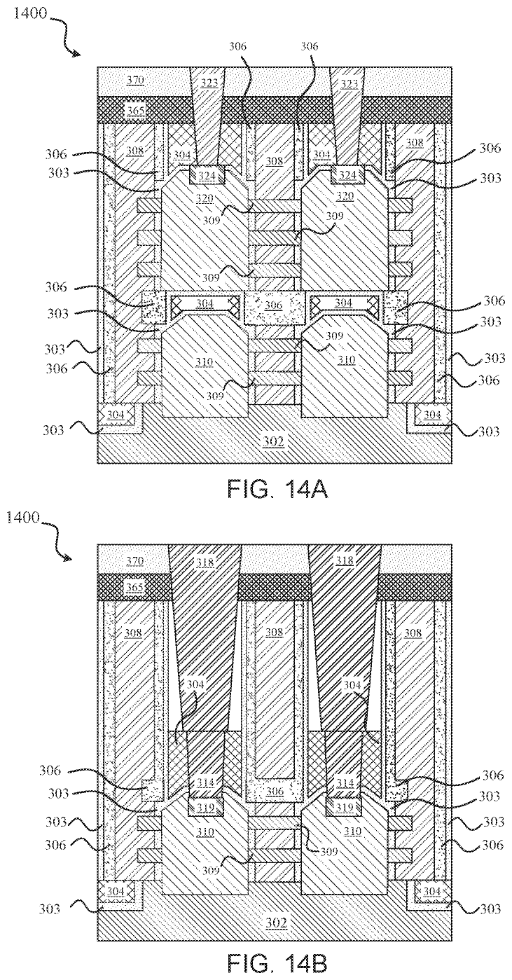

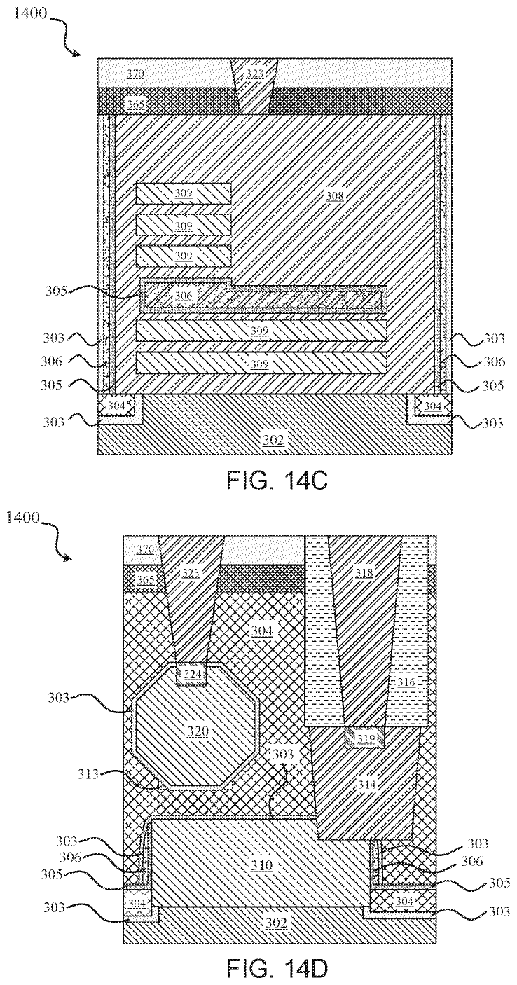

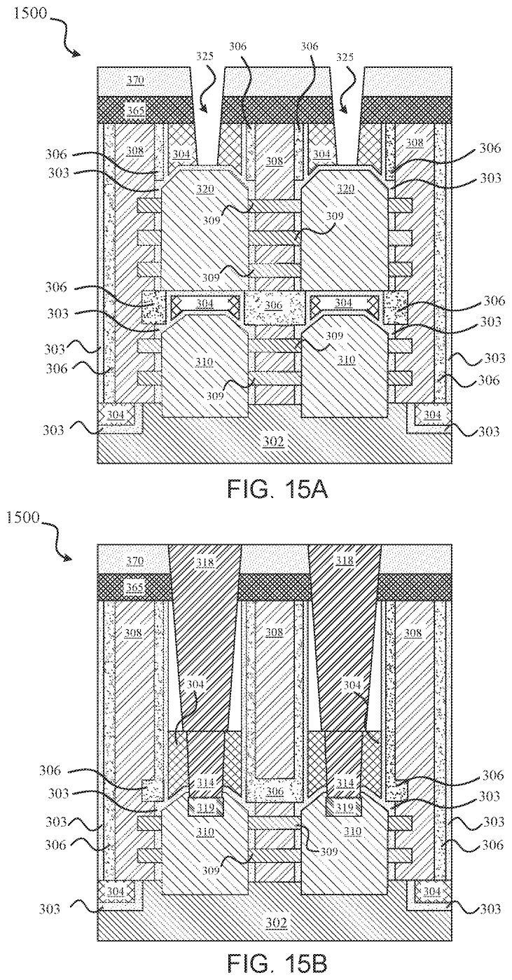

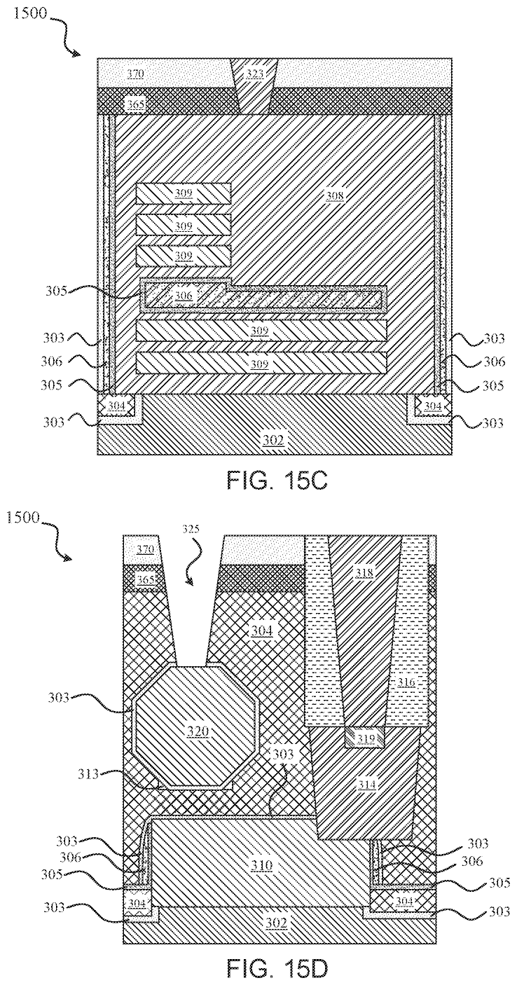

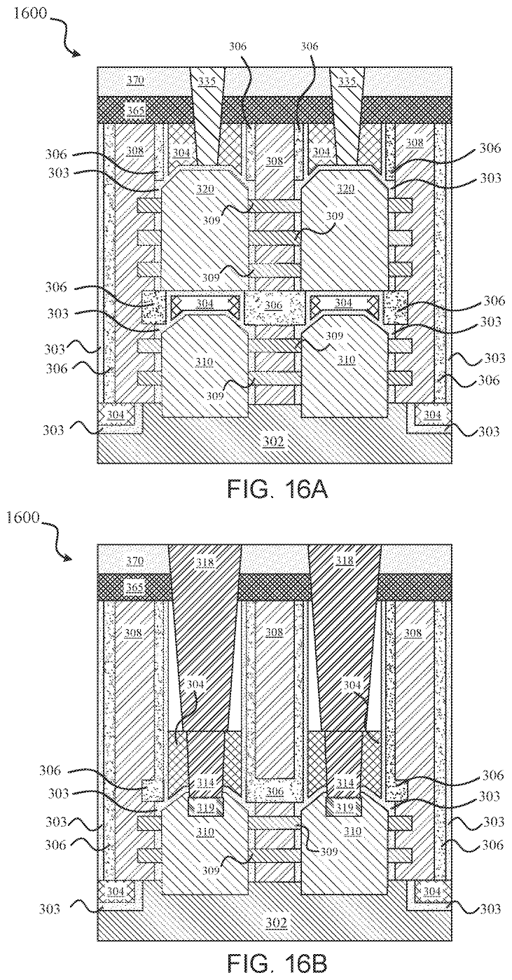

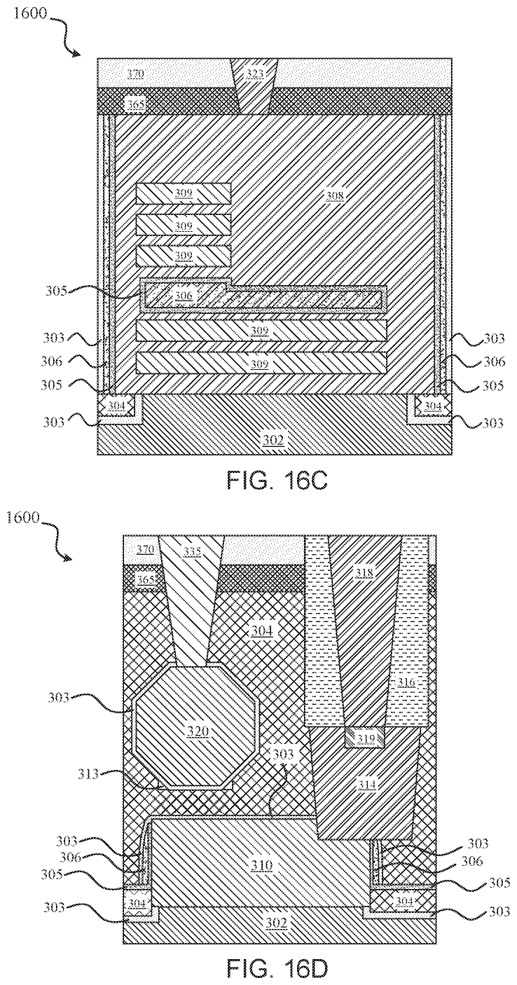

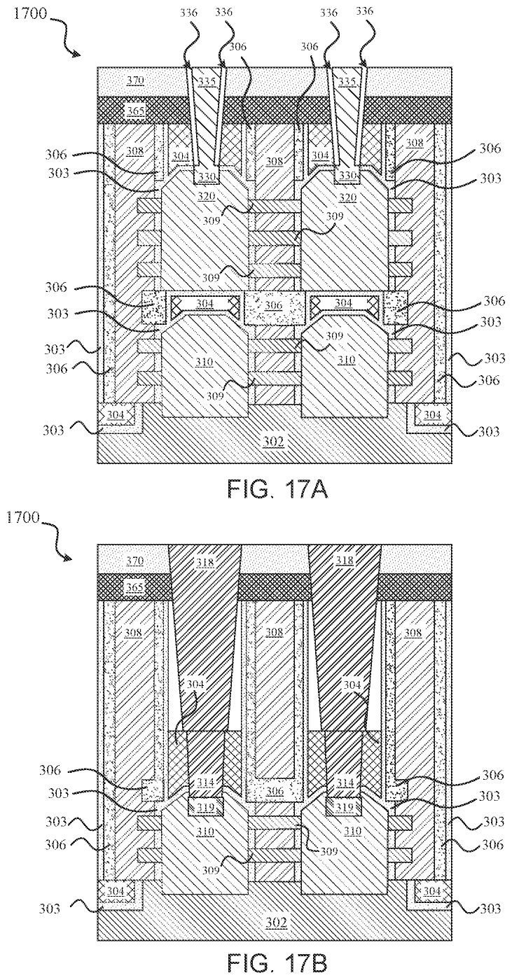

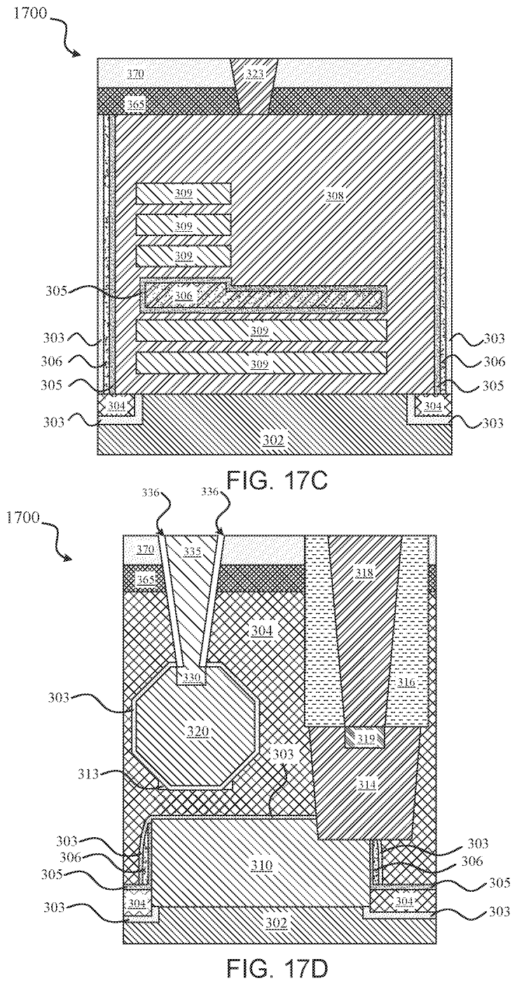

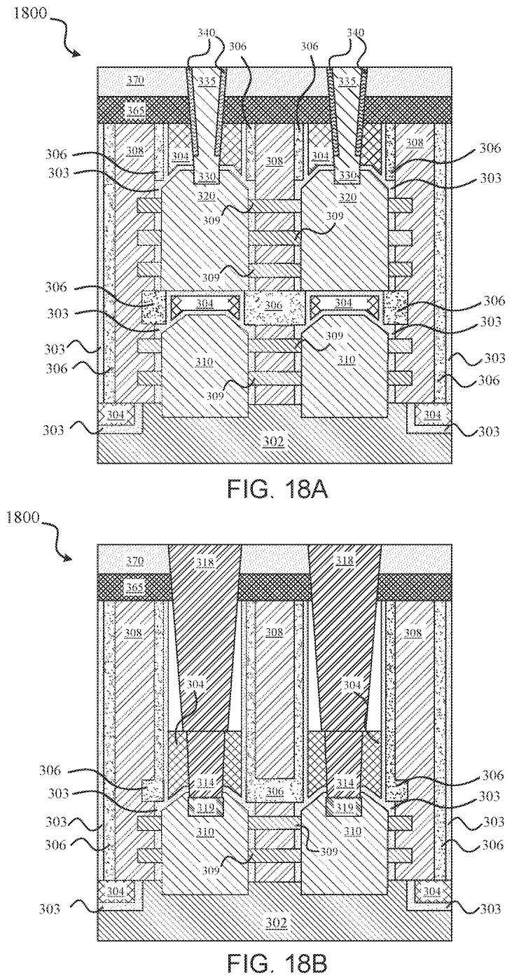

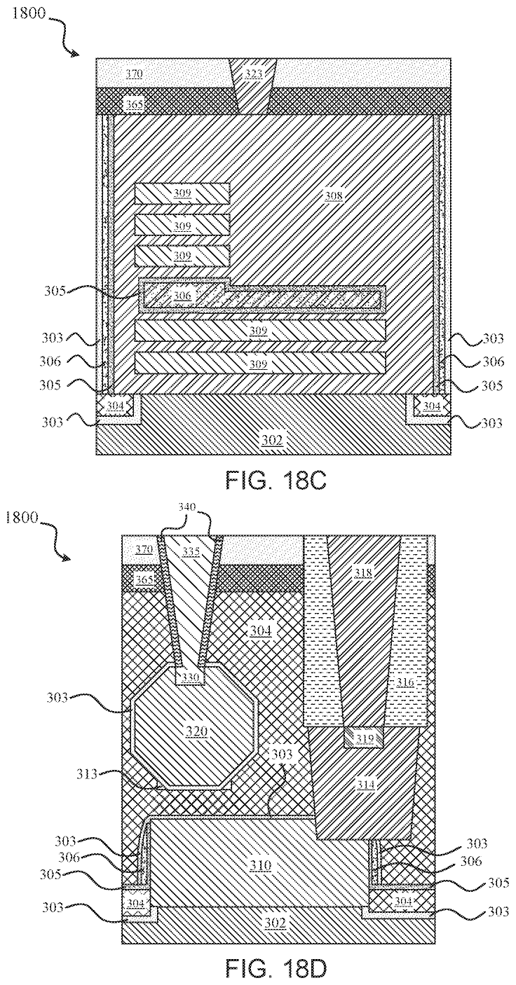

Referring now to FIG. 2, a top down view of a multi-silicide structure 200 with various cross-sections are depicted, according to some embodiments. Multi-silicide structure 200 may be the same/similar structure as structures 100 (FIG. 1), 200 (FIG. 2), 300 (FIG. 3), 400 (FIG. 4), 500 (FIG. 5), 600 (FIG. 6) 700 (FIG. 7), 800 (FIG. 8), 900 (FIG. 9), 1000 (FIG. 10), 1100 (FIG. 11), 1200 (FIG. 12), 1300 (FIG. 13), 1400 (FIG. 14), 1500 (FIG. 15), 1600 (FIG. 16), 1700 (FIG. 17), and/or 1800 (FIG. 18). As discussed further herein, FIGS. 3A-17D may depict intermediate steps in the process of forming a multi-silicide stacked FET structure 1800 (FIG. 18A-D). These figures depict the stacked FET structure and the intermediate steps using various cross-sections, according to some embodiments. FIG. 2 depicts a simplified top down view of a multi-silicide structure 200 and its various cross-sections. These cross-sections may be the same/similar cross-sections referenced in FIGS. 3A-18D.

The top down view of multi-silicide structure 200 includes metal contacts 210, 220, 230, and 215. The various cross-sectional views referenced herein (and depicted in FIG. 2), include an A view 240, a B view 250, a C view 260, and a D view 270. These may also be referred to herein as cross-section A (240), cross-section B (250), cross-section C (260), and cross-section D (270). In some instances, cross-section C 260 may be a cross-section through/along a gate region of a stacked transistor structure, and cross-section D 270 may be a cross-section through/along a source/drain (S/D) region of a stacked transistor structure.

Referring now to FIGS. 3A-18D, FIGS. 3A-17D depict intermediate steps in the process of forming multi-silicide stacked FET structure 1800, according to some embodiments. FIGS. 18A-18D depict the fully formed multi-silicide stacked FET structure 1800, according to some embodiments. Although FIGS. 3A-17D are discussed in relation to multi-silicide stacked FET structure 1800, the same/similar steps may be used to form stacked FET structure 100 (FIG. 1), in some instances.

In some instances, FIGS. 3A, 4A, 5A, 6A, 7A, 8A, 9A, 10A, 11A, 12A, 13A, 14A, 15A, 16A, 17A, and 18A may correspond to the cross-section A view (240) depicted in FIG. 2. FIGS. 3B, 4B, 5B, 6B, 7B, 8B, 9B, 10B, 11B, 12B, 13B, 14B, 15B, 16B, 17B, and 18B may correspond to the cross-section B view (250) depicted in FIG. 2. FIGS. 3C, 4C, 5C, 6C, 7C, 8C, 9C, 10C, 11C, 12C, 13C, 14C, 15C, 16C, 17C, and 18C may correspond to the cross-section C view (260) depicted in FIG. 2. FIGS. 3D, 4D, 5D, 6D, 7D, 8D, 9D, 10D, 11D, 12D, 13D, 14D, 15D, 16D, 17D, and 18D may correspond to the cross-section D view (270) depicted in FIG. 2.

Referring to FIGS. 3A-3D, various cross-sectional views (A-D) of intermediate step 300 (also referred to herein as intermediate structure 300) of forming a multi-silicide stacked FET structure 1800 are depicted, according to some embodiments. Intermediate structure 300 includes a substrate 302 with NFETs 310 and PFETs 320 stacked on top of the substrate 302. NFETs 310 and PFETs 320 may include nanosheets 309. In some instances, as depicted, intermediate structure 300 may include metals 308, along with various dielectric/dielectric insulator materials (such as dielectric 303, 304, 305, and 306). In some instances, substrate 302, NFETs 310, PFETs 320, nanosheets 309, and dielectrics 303, 304, 305, and 306 may correspond with substrate 102, NFETs 110, PFETs 120, nanosheets 109, and dielectrics 103, 104, 105, and 106 (discussed herein and depicted in FIG. 1). FIG. 3D (the D cross-sectional view of intermediate structure 300) may include dielectric 313. Dielectric 313 may be materials such as SiN, SiO₂, etc. In some instances, intermediate structure 300 may be depicted after a chemical mechanical planarization (CMP) smoothing/polishing step.

Referring to FIGS. 4A-4D, various cross-sectional views of intermediate step 400 of forming a multi-silicide stacked FET structure are depicted, according to some embodiments. In some instances, intermediate step 400 includes depositing dielectric layers 365 and 370. Dielectric layers 365 and 370 (also referred to herein as dielectric 365 and dielectric 370) may correspond to dielectric 165 and 170 (FIG. 1), in some instances. In some instances, dielectric layers 365 and 370 may be interlayer dielectric (ILD). Dielectric layers 365 and 370 may be deposited through methods such as atomic layer deposition (ALD), chemical vapor deposition (CVD), laser induced chemical vapor deposition (LCVD), and/or any other applicable deposition technique.

Referring to FIGS. 5A-5D, various cross-sectional views of intermediate step 500 of forming a multi-silicide stacked FET structure are depicted, according to some embodiments. Intermediate step 500 may include defining the pattern 311 (e.g., boundaries, area, outline, etc.) of trenches/vias to be formed. This may include depositing hard mask oxide (HMO) and etching (for example, through reactive ion etching (RIE)) a pattern 311 for the trenches/vias to be formed through the various dielectric (370, 365, 304, 303) to the NFETs 310. Utilizing an HMO may offer an improved trench profile control (for example, compared to simply etching trenches/vias without HMO).

Referring to FIGS. 6A-6D, various cross-sectional views of intermediate step 600 of forming a multi-silicide stacked FET structure are depicted, according to some embodiments. Intermediate step 300 may include forming trenches 312 (also referred to as openings and/or vias). To form trenches 312, the HMO and pattern 311 may be stripped (for example, using lithography and/or etching techniques). As depicted in FIGS. 6B and 6D, trench(es) 312 may extend to the NFETs 310.

Referring to FIGS. 7A-7D, various cross-sectional views of intermediate step 700 of forming a multi-silicide stacked FET structure are depicted, according to some embodiments. Intermediate step 700 may include filling trenches 312 with metal 314 (for example, through metal deposition). The metal 314 may be deposited through methods such as ALD, CVD, LCVD, and/or any other applicable deposition technique. In some instances, metal 314 may be cobalt (Co) and/or tungsten (W). In some instances, metal 314 and metal 308 may be different metal materials. For example, in instances where metal 314 is Co, metal 308 may be W, and in instances where metal 314 is W, metal 308 may be Co. In some instances, metal 314 and metal 308 may be the same metal material(s).

Referring to FIGS. 8A-8D, various cross-sectional views of intermediate step 800 of forming a multi-silicide stacked FET structure are depicted, according to some embodiments. In some instances, intermediate step 800 includes recessing the metals 314 to create trenches 315 (these can also be referred to as vias 315 or openings 315). Recessing the metals 314 may include etching/removing portions of metals 314 (along with, in some instances, portions of dielectrics 365, 370, and 304) such that there is only a small/smaller portion of metals 314 and their surrounding dielectric 304 remaining. In some instances, the etching/removing may be done using reactive ion etching (RIE), ion beam etching (IBE), or any other patterning/etching process.

Referring to FIGS. 9A-9D, various cross-sectional views of intermediate step 900 of forming a multi-silicide stacked FET structure are depicted, according to some embodiments. Intermediate step 900 may include filling the created trenches 315 with interlayer dielectric (ILD) fill 316 (referred to herein as ILD 316). In some instances, the ILD 316 may be a material such as silicon dioxide (SiO₂) or any other applicable dielectric material. ILD 316 may be deposited as fill using methods such as ALD, CVD, LCVD, and/or any other applicable deposition technique.

Referring to FIGS. 10A-10D, various cross-sectional views of intermediate step 1000 of forming a multi-silicide stacked FET structure are depicted, according to some embodiments. Intermediate step 1000 may include patterning trenches 317 through a portion of ILD(s) 316 (also referred to as openings 317 and/or vias 317). In some instances, as depicted in FIGS. 10B and 10D, the openings 317 may extend to metals 314 (however, in some instances, the openings 317 may not extend through the metals 314). This may allow the material(s) filling the openings 317 (discussed further herein) to have direct contact with metals 314. In some instances, patterning trenches 317 may be done using reactive ion etching (RIE), ion beam etching (IBE), or any other patterning/etching process.

Referring to FIGS. 11A-11D, various cross-sectional views of intermediate step 1100 of forming a multi-silicide stacked FET structure are depicted, according to some embodiments. Intermediate step 1100 may include filling the created trenches 317 with metal fill 318. Metal 318 may be deposited (i.e., to fill trenches 317) using methods such as ALD, CVD, LCVD, and/or any other applicable deposition technique. In some instances, when performing multiple fill steps (for example, by performing metal fill 314 and metal fill 318), the materials used for the fill, size of the trenches/vias, etc. may be customized, different, etc., In some instances, metal 318 may be metal materials such as W, Co, etc. In some instances, metals 314 and 318 are a same material. For example, if metal 314 is Co, metal 318 is Co, if metal 314 is W, metal 318 is W, etc. In some instances, metals 314 and 318 may be different metal materials. In some instances, metals 314 and 318 may be metal contacts for the NFETs 310 (e.g., may contact/connect NFETs 310 with other components of the semiconductor).

Referring to FIGS. 12A-12D, various cross-sectional views of intermediate step 1200 of forming a multi-silicide stacked FET structure are depicted, according to some embodiments. Intermediate step 1200 may include creating trenches/openings 322 in the PFET 320 region of the semiconductor structure. Creating the trenches 322 may include recessing, or removing, portions of the dielectric 365, 370, and 304 to form trenches 322. In some instances, the recessing/etching/removing may be done using RIE, ion beam etching (IBE), or any other patterning/etching process. In some instances, the trenches 322 may be formed up to, or almost up to, the PFETs 320. For instance, as depicted in FIG. 12A, the trenches 322 may be formed through dielectrics 370, 365, and 304, and up to a thin layer of dielectric 303 above PFETs 320. This may help prevent any unwanted etching of PFETs 320.

Referring to FIGS. 13A-13D, various cross-sectional views of intermediate step 1300 of forming a multi-silicide stacked FET structure are depicted, according to some embodiments. Intermediate step 1300 may include filling trenches 322. Trenches 322 may be filled using methods such as ALD, CVD, LCVD, and/or any other applicable deposition technique. In some instances, as depicted in FIG. 13A, the trenches 322 may be filled with a metal 323 (for example, W, Co, etc.). In some instances, trenches 322 may be filled with a silicide such as silicide 335 (discussed and depicted further herein). In these instances, the silicide may be filled prior to formation of the PFET silicide 330 (FIGS. 17A and D), but may be filled before or after the formation of the NFET silicide 319 (FIGS. 14B and D).

In some instances, instead of performing intermediate steps 1200 (FIGS. 12A-D) and 1300 (FIGS. 13A-D), the process of forming a multi-silicide stacked FET structure may go from intermediate step 1100 (FIGS. 11A-D) to intermediate step 1400 (FIGS. 14A-D). In these instances, for intermediate step 1400, the A cross-section (for example, as depicted in FIG. 14A) may appear the same/similar as the A cross-section depicted in FIG. 11A.

Referring now to FIGS. 14A-14D, various cross-sectional views of intermediate step 1400 of forming a multi-silicide stacked FET structure are depicted, according to some embodiments. Intermediate step 1400 may include forming NFET silicides 319. In some instances, silicides 319 may be formed by depositing a metal/silicide and providing a laser annealing to reach the metal/silicide with the epitaxial layer. Silicides 319 may act as a junction between NFETs 310 and metal contacts 314 and 318. In some instances, silicides 319 may be materials such as Ti-silicides.

In some instances, for example, when the process of forming a multi-silicide stacked FET structure includes intermediate steps 1200 (FIGS. 12A-12D) and 1300 (FIGS. 13A-13D), intermediate step 1400 may further include forming PFET silicides 324. For example, at a same/similar time that NFET silicides 319 are being formed, PFET silicides 324 may be formed. In these instances, PFET silicides 324 may be a same/similar material as NFET silicides 319.

In some instances, for example, when the process of forming a multi-silicide stacked FET structure does not include intermediate steps 1200 (FIG. 12) and 1300 (FIG. 13), intermediate step 1400 may only include forming NFET silicides 319. In these instances, the A cross-section during intermediate step 1400 may appear the same/similar as the A cross-section depicted in FIG. 11A (for example, instead of the A cross-section depicted in FIG. 14A). In these instances, the D cross-section (for example, depicted in FIG. 14D) may not include metal 323 or silicide 324.

Referring to FIGS. 15A-15D, various cross-sectional views of intermediate step 1500 of forming a multi-silicide stacked FET structure are depicted, according to some embodiments. Intermediate step 1500 may include forming trenches 325 (for example, using RIE, IBE, or any other patterning/etching process). In some instances, for example, when the process of forming a multi-silicide stacked FET structure does not include intermediate steps 1200 (FIGS. 12A-12D) and 1300 (FIGS. 13A-13D), trenches 325 may be the first trenches/openings created in the PFET 320 region of the semiconductor structure (as trenches 322 may not have been created). In these instances, creating the trenches 325 may include recessing, or removing, portions of the dielectric 365, 370, and 304 to form trenches 325. In some instances, the trenches 325 may be formed up to, or almost up to, the PFETs 320. For instance, as depicted in FIG. 15A, the trenches 325 may be formed through dielectrics 370, 365, and 304, and up to a thin layer of dielectric 303 above PFETs 320. This may help prevent any unwanted etching of PFETs 320.

In some instances, as discussed herein, the process of forming a multi-silicide stacked FET structure includes intermediate steps 1200 (FIGS. 12A-12D) and 1300 (FIGS. 13A-13D) and forming PFET silicides 324 (for example, as depicted in FIGS. 14A and D). In these instances, intermediate step 1500 may include removing metals 323 and silicides 324 (along with the creation of trenches 325). For instance, a system may be designed to form silicides 324 concurrently with silicides 319, however silicides 324 may not be desired (for example, because they may be a same material as silicides 319), therefore they may be removed after they are formed.

Referring now to FIGS. 16A-16D, various cross-sectional views of intermediate step 1600 of forming a multi-silicide stacked FET structure are depicted, according to some embodiments. Intermediate step 1600 may include filling trenches 325 with a silicide material 335 (referred to herein as silicides 335). In some instances, silicides 335 may act as contacts between PFETs 320 and other components of a semiconductor system. Therefore, silicides 335 may also be referred to herein as silicide contacts 335. In some instances, silicides 335 may be a different silicide material than NFET silicides 319. For example, NFET silicides 319 may contain titanium (i.e., may be Ti-silicides) and silicides 335 may contain ruthenium (i.e., may be Ru-silicides). This way, the silicide material(s) used in the NFET region and the PFET region may be customized/tailored to the needs of the specific region, instead of using a single silicide throughout both the NFET and PFET regions. Trenches 325 may be filled using methods such as ALD, CVD, LCVD, and/or any other applicable deposition technique.

In some instances, PFET silicides 330 (depicted in FIGS. 17A and D) may be formed along with the silicide contacts 335. For example, trenches 325 may have been patterned/etched through portions of dielectric 303 and PFET 320 in order to create space for the silicides 330. In another example, in instances where intermediate step 1500 included removing metals 323 and silicides 324, trenches 325 may have been created from the open space left from the removal of the metals 323 and silicides 324 and may have included the areas where silicides 324 had been formed. In this example, when trenches 325 were filled, the silicide fill may have filled the spaces previously taken up by metals 323 and silicides 324.

In some instances, as discussed herein, trenches 325 may have been formed up to PFET 320 and/or dielectric 303. In these instances, filling the trenches with a silicide material may form silicide contacts 335 but not PFET silicides 330 (depicted in FIGS. 17A and D). Therefore, in some instances (not depicted), PFET silicides 330 may be formed using the same/similar methods as forming NFET silicides 319 (FIGS. 14A-14D).

In some instances, PFET silicides 330 and NFET silicides 319 are different materials, in order to allow for tailoring/customization of the silicide materials to meet the needs of their specific regions (for example, PFET region and/or NFET region). For example, PFET silicides 330 may be Ru-silicides and NFET silicides 319 may be Ti-silicides. In some instances, PFET silicides 330 (also referred to herein as silicide junctions 330) may be a same/similar material as silicide contacts 335 (as they are both located in the PFET 320 region of the semiconductor).

Referring to FIGS. 17A-17D, various cross-sectional views of intermediate step 1700 of forming a multi-silicide stacked FET structure are depicted, according to some embodiments. Intermediate step 1700 may include forming small openings/vias 336 along the sidewalls of the silicide contacts 335. As discussed herein, because of the patterning method used for a silicide material such as Ru (for example, compared to Ti-silicide), openings may be created/formed in the silicide contacts 335. In some instances, openings 336 may be formed using a subtractive etch method.

To finish forming multi-silicide stacked FET structure 1800 (FIG. 18), a dielectric 340, such as a low-k dielectric, may be deposited in the created openings 336. This may result in low-k dielectric sidewalls 340 surrounding the silicide contacts 335. In some instances, low-k dielectric sidewalls 340 may be a low-k dielectric such as SiCOH, parylene, SiN, SiO₂, or any other low-k dielectric material).

Referring to FIGS. 18A-18D, various cross-sectional views of a fully-formed multi-silicide stacked FET structure 1800 are depicted, according to some embodiments. In some instances, multi-silicide stacked FET structure 1800 may correspond with silicide structure 100 (FIG. 1). Multi-silicide stacked FET structure 1800 has stacked NFETs 310 and PFETs 320. NFETs 310 may have silicides 319 and metal contacts 314 and 318. In some instances, NFET silicide 319 may be described as proximately connected to NFET 310 and PFET silicide 330 may be described as proximately connected to PFET 320. The term “proximately connected” may be used herein to describe a connection between two components, specifically components that are directly connected to or touching each other. For example, metal contact 314 may be described as proximately connected to NFET silicide 319 as they are in direct contact with each other. However, metal contact 318 may not be described as proximately connected to NFET silicide 319, as they are not in direct contact with each other and instead metal contact 314 separates the two. Even though components may not be proximately connected to each other, they still may have an electrical connection and may be described as electrically connected to each other.

Although NFET silicides 319 may be described as proximately connected to NFETs 310 and PFET silicides 330 may be described as proximately connected to PFETs 320, NFET silicides 319 may be considered a part of/within NFET 310, and PFET silicides 330 may be considered part of/within PFET 320. Therefore, proximately connected to may also refer to being directly connected to one or more components of the NFET/PFET. For example, silicides 330 and 319 may be proximately connected to various components of their respective PFET and NFET, and may also be considered a part of their respective PFET and NFET. In some instances, silicide contacts 335 may be described as proximately connected to PFET silicides 330, which may include instances where contacts 335 and PFET silicides 330 are part of the same silicide fill step (and there is no separation/distinction between the PFET silicides and the contacts 335.

In some instances, NFET silicides 319 may be Ti-silicides. PFETs 320 may have silicides 330 and silicide contacts 335. As discussed herein, PFET silicides 330 may be a different material (for example, Ru-silicides) than NFET silicides 319, to allow for better tailored/customized materials for their respective regions. PFET silicides 330 may serve as a junction between PFETs 320 and silicide contacts 335, and NFET silicides 319 may serve as a junction between NFETs 310 and metal contacts 314 and 318.

In some instances, multi-silicide stacked FET structure 1800 includes low-k dielectric sidewalls 340 surrounding the sidewalls of silicide contacts 335. The low-k dielectric sidewalls 340 may have numerous advantages, including decreasing/reducing capacitance and avoiding electrical shorts (such as top-epi shorts).

Although multi-silicide stacked FET structure 1800 depicts NFETs 310 as the bottom FET and PFETs 320 as the top FET, this is an example structure and other alternative structures may be utilized. For example, in some instances PFET 320 may be a bottom FET and NFET 310 may be a top FET. In these instances, the top silicides 330 may be Ti-silicides and the bottom silicides 319 may be Ru-silicides. Further, in some instances, contacts 335 may become metal contacts 314 and/or 318 and contacts 314 and 318 may become silicide contacts 335. The dielectric sidewalls 340 may also be a part of the bottom FET contacts, in an alternative structure. Further, although multi-silicide stacked FET structure 1800 depicts two NFETs 310 and two PFETs 320, any number of NFETs and PFETs (and their corresponding components, such as silicides 330 and 319, contacts 335, 314, and 318, etc.) may be used.

The present invention may be a system, a method, a computer program product, etc. at any possible technical detail level of integration.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks. The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to some embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A multi-silicide semiconductor structure, wherein the multi-silicide semiconductor structure comprises:
an NFET;
a PFET;
an NFET silicide proximately connected to the NFET, wherein the NFET silicide is a first material; and
a PFET silicide proximately connected to the PFET, wherein the PFET silicide is a second material different than the first material.

2. The multi-silicide semiconductor structure of claim 1, wherein the second material is Ru-silicide.

3. The multi-silicide semiconductor structure of claim 1, wherein the first material is Ti-silicide.

4. The multi-silicide semiconductor structure of claim 1, further comprising:
a silicide contact for the PFET; and
low-k dielectric sidewalls surrounding the silicide contact.

5. The multi-silicide semiconductor structure of claim 1, wherein the second material has a lower Schottky barrier height than the first material.

6. The multi-silicide semiconductor structure of claim 1, wherein the NFET and the PFET are stacked transistors.

7. The multi-silicide semiconductor structure of claim 1, wherein the NFET and the PFET are nanosheet FETs.

8. The multi-silicide semiconductor structure of claim 1, further comprising a metal contact proximately connected to the NFET silicide.

9. A system, wherein the system comprises:
a multi-silicide semiconductor structure, wherein the multi-silicide semiconductor structure comprises:
an NFET;
a PFET;
an NFET silicide proximately connected to the NFET, wherein the NFET silicide is a first material;
a PFET silicide proximately connected to the PFET, wherein the PFET silicide is a second material different than the first material; and
a silicide contact for the PFET.

10. The system of claim 9, wherein the second material is Ru-silicide.

11. The system of claim 9, wherein the first material is Ti-silicide.

12. The system of claim 9, further comprising:
low-k dielectric sidewalls surrounding the silicide contact.

13. The system of claim 9, wherein the second material has a lower Schottky barrier height than the first material.

14. The system of claim 9, further comprising a metal contact proximately connected to the NFET silicide.

15. A method of forming a multi-silicide semiconductor structure, the method comprising:
forming an NFET silicide proximately connected to an NFET, wherein the NFET silicide is a first material; and
forming a PFET silicide proximately connected to a PFET, wherein the PFET silicide is a second material different than the first material.

16. The method of claim 15, wherein the second material is Ru-silicide.

17. The method of claim 15, wherein the first material is Ti-silicide.

18. The method of claim 15, further comprising:
depositing a metal fill proximately connected to the NFET, resulting in a metal contact for the NFET; and
depositing a silicide fill proximately connected to the PFET, resulting in a silicide contact for the PFET.

19. The method of claim 18, further comprising:
etching vias along sidewalls of the silicide contact; and
filling the small openings with a low-k dielectric, resulting in low-k dielectric sidewalls surrounding the silicide contact.

20. The method of claim 18, wherein the NFET silicide is formed between the metal contact and the NFET, and wherein the metal contact is proximately connected to the NFET silicide.
